(19) United States
(12) Patent Application Publication
(10) Pub. No.: US 2016/0181155 A1
(43) Pub. Date: Jun. 23, 2016

(54) METHOD FOR MAKING AN INTEGRATED CIRCUIT IN THREE DIMENSIONS

(71) Applicant: Commissariat a L'Energie Atomique et aux Energies Alternatives, Paris (FR)

(72) Inventors: Fabien DEPRAT, Grenoble (FR); Perrine BATUDE, Dijon (FR); Yves MORAND, Grenoble (FR); Heimanu NIEBOJEWKSI, Grenoble (FR); Nicolas POSSEME, Grenoble (FR)

(73) Assignee: Commissariat a L'Energie Atomique et aux Energies Alternatives, Paris (FR)

(21) Appl. No.: 14/976,958

(22) Filed: Dec. 21, 2015

(30) Foreign Application Priority Data
Dec. 22, 2014 (FR) 14 63111

(51) Int. Cl. H01L 21/768

(52) U.S. Cl. CPC H01L 21/76895; H01L 21/76802; H01L 21/76831

(57) ABSTRACT

Method of making an integrated circuit, comprising at least the following steps:

a) form a first semiconducting or conducting element, covered with a first insulating layer on which there is a second semiconducting or conducting element, covered with a second insulating layer;

b) form an opening passing through at least the second insulating layer, exposing a portion of the second element and opening up at least partly on the second element or adjacent to the second element;

c) form a spacer located at the second element and comprising at least one dielectric material located at least between the second element and the opening;

d) prolong the opening through the first insulating layer as far as the first element; and

e) fill the opening with at least one conducting material, so as to form a contact.

FIG 1G.

### TECHNICAL DOMAIN

This invention relates to a method of making an integrated circuit in three dimensions (3D), and more particularly a method of forming so-called 3D contacts to electrically connect elements in non-adjacent levels.

### STATE OF PRIOR ART

Technologies based on stacking of chips or circuits on several levels, currently referred to by the term <<3D integration>>, provide means of increasing the integration density of components and reducing times due to interconnections by reducing their lengths.

In some cases, it is required to electrically connect elements of non-adjacent levels, in other words separated by one or several intermediate levels. Contacts connecting elements of non-adjacent levels are then usually formed at a given distance from access zones to devices of intermediate levels, to avoid disturbing operation of these devices of intermediate levels passed through. This prevents a short circuit between an intermediate level access zone and the contact. Nevertheless, there is a reduction in the integration density as a result.

Therefore, the problem arises of making 3D contacts for electrically connecting elements of non-adjacent levels while remaining electrically insulated from access zones of intermediate levels passed through.

The problem also arises of increasing the integration density of circuits comprising such 3D contacts.

### Presentation of the Invention

One aim is to solve these problems.

It is disclosed a method of making a self-aligned 3D contact to electrically connect elements of non-adjacent levels of a 3D integrated circuit, while being electrically insulated from one or several access zones to one or several devices of one or several intermediate levels passed through.

In general, in order to make a contact, an opening is formed through one or several circuit levels, for example by photolithography and etching, and then filled with conducting material.

We refer to a self-aligned contact relative to one or several access zones because its manufacturing requires the manufacturing of a dielectric spacer between this contact and the access zone(s) regardless of technological variations related to its manufacturing, for example regardless of variations in the position of a photolithography tool used (for example of the UV type or an electron beam). The opening is formed so as to expose one or several access zones to one or several devices of one or several intermediate levels passed through and to open up at least partly on or adjacent to this access zone(s). One or several spacers comprising a dielectric material are then formed to electrically insulate the contact from this or these access zones.

One embodiment relates to a method of making an integrated circuit, comprising at least the following steps:

a) form a first semiconducting or conducting element covered with a first insulating layer on which there is a second semiconducting or conducting element, covered with a second insulating layer;

b) form an opening passing through at least the second insulating layer, exposing a portion of the second element and opening up at least partly on or adjacent to the second element;

c) form a spacer located at the second element and comprising at least one dielectric material located at least between the second element and the opening;

d) prolong the opening through the first insulating layer as far as the first element; and

e) fill the opening with at least one conducting material, so as to form a contact.

One advantage of a method like that described above lies in the reduction in the distance between the contact and the second element, because the contact opening is formed such that it exposes a portion of the second element, and opens up on or at the side of, or next to, the second element, the contact being insulated from the second element by the spacer. The result is an increase in the integration density of the circuit.

According to one embodiment, during step b), the opening may be formed as far as the first insulating layer.

According to another embodiment, the first and second insulating layers may have the same nature, in other words they comprise one or several similar dielectric materials and during step b), the opening may pass partly through the first insulating layer.

According to one embodiment, step c) to form the spacer may comprise at least the following steps:
isotropic etching of part of the second element including at least said portion of the second element so as to form a cavity located between the first and second insulating layers;
deposit at least one dielectric material, for example conforming, at least on the walls of the opening and in the cavity; and
eliminate the dielectric material except in the cavity.

The deposition of the at least one dielectric material on the walls of the opening and in the cavity, which corresponds to a supplemental material in addition to the materials already present at the walls of the opening and in the cavity, does not correspond to an oxidation which is not an addition of a supplemental material but a transformation of features of a material already present.

One advantage of a method like that described above lies in the fact that it can be used to form a contact with a small diameter (or width), for example of the order of a few nanometers. This is related to the fact that said spacer is not formed in the contact opening but it is located between the first and second insulating layers, adjacent to the opening.

According to another embodiment, one dimension of the cavity approximately perpendicular to the principal axis of the opening may be such that part of the cavity is not filled with dielectric material after deposition of the dielectric material. Thus, the combination of the part of the cavity that is not filled with dielectric material and the spacer may form an insulating zone between the second element and the contact.

A cavity dimension approximately perpendicular to the principal axis of the opening means a cavity dimension approximately parallel to the upper surface of the first insulating layer.

One advantage of such a variant lies in the fact that the electrical insulation between the contact and the second element is improved.

According to one embodiment, during step b), the opening may be formed so as to open up only partly on the second element.

According to one embodiment, during step b), the opening may be formed so as to open up only partly on the second element or adjacent to the second element, and the spacer may be formed by oxidation of at least part of said portion of the second element that was exposed by formation of the opening.

One advantage of a method like that described above lies in the small number of manufacturing steps because the spacer is then formed during a single local oxidation step of at least part of the portion of the second element that was exposed during formation of the opening.

According to one embodiment, during step e) to fill the opening, an electrically conducting barrier layer may previously be formed in the opening before formation of the conducting material. The barrier layer may in particular avoid diffusion of the conducting material to the first and second insulating layers and to said spacer, and thus improve the bonding of the conducting material deposited in the opening.

According to one embodiment, the first element may be an active zone of at least a first transistor or a first metallic line, and/or the second element may be an active zone of at least one second transistor or a second metallic line.

According to one embodiment, during step a), at least one semiconducting or conducting intermediate element covered with an intermediate insulating layer may be arranged between the first insulating layer and the second element. In this case, the method described above may also comprise the following steps performed for the or each intermediate element, between steps c) and d):
prolong the opening through the intermediate insulating layer covering said intermediate element, such that the opening exposes a portion of said intermediate element and opens up at least partly on or adjacent to said intermediate element; and
form an intermediate spacer located at said intermediate element level and comprising at least one dielectric material arranged at least between said intermediate element and the opening.

### BRIEF DESCRIPTION OF THE DRAWINGS

Other characteristics and advantages of the invention will become clearer after reading the following description with reference to the appended drawings, given solely for illustrative purposes and that are in no way limitative.

FIGS. 1A to 1G are sectional views diagrammatically illustrating successive steps in an example method for making a self-aligned contact.

FIGS. 2A to 2D are sectional views diagrammatically illustrating successive steps of a variant of the method in FIGS. 1A-1G.

FIGS. 3A to 3E are sectional views diagrammatically illustrating successive steps of another example method of making a self-aligned contact.

FIGS. 3F to 3I are sectional views diagrammatically illustrating successive steps of another example method of making a self-aligned contact.

FIGS. 4A to 4D are sectional views diagrammatically illustrating successive steps of another variant of the method in FIGS. 1A-1G.

FIG. 5 is a sectional view diagrammatically illustrating an example of a structure obtained by a method according to one embodiment.

FIG. 6 is a sectional view diagrammatically illustrating another example of a structure obtained by a method according to one embodiment.

FIG. 7 is a sectional view diagrammatically illustrating another example of a structure obtained by a method according to one embodiment.

Identical, similar or equivalent parts in the various figures have the same numeric references so as to facilitate changing from one figure to the other.

The various parts shown in the figures are not all necessarily at the same scale, to make the figures more easily legible.

### DETAILED PRESENTATION OF PARTICULAR EMBODIMENTS

The following describes a method of making a self-aligned 3D contact to electrically connect elements of non-adjacent levels of an integrated circuit, while remaining electrically insulated from access zones to devices of intermediate levels passed through.

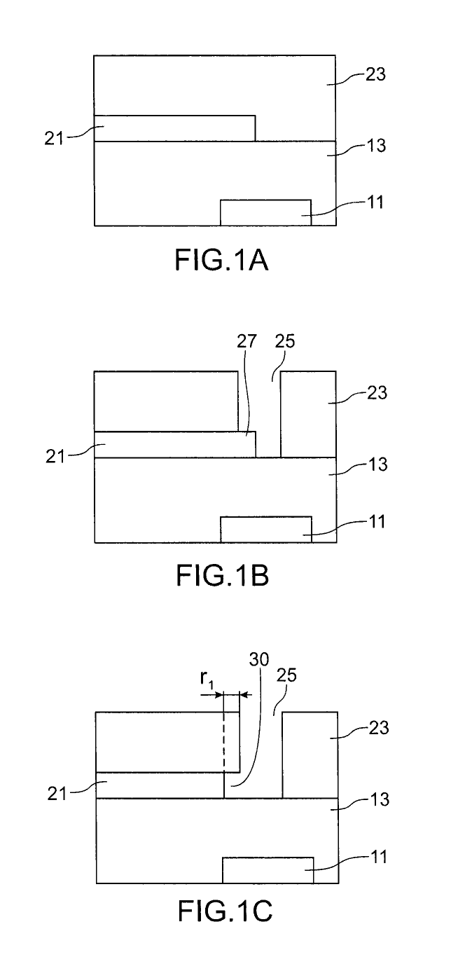

FIGS. 1A to 1G are sectional views diagrammatically illustrating successive steps of an example method of making a self-aligned 3D contact.

FIG. 1A illustrates two adjacent levels of a 3D integrated circuit. The first level includes a first element 11, comprising at least one semiconducting material or at least one conducting material, covered with a first insulating layer 13 comprising at least one dielectric material. The second level, located on the first level, comprises a second element 21, comprising at least one semiconducting material or at least one conducting material, covered with a second insulating layer 23 comprising at least one dielectric material.

The second level may for example be formed by transfer onto the first insulating layer 13 or by epitaxial growth, or by deposition and laser recrystallization. For example, the first and second levels are formed on a substrate (not shown), other levels possibly being interposed between the substrate and the first level.

The first element 11 may for example comprise an access zone to one or several devices, for example one or several first transistors, or a first metallic line. The second element 21 may for example comprise an access zone to one or several devices, for example one or several second transistors, or a second metallic line.

As examples of orders of magnitude of the dimensions, the thickness (dimension approximately perpendicular to the interface between insulating layers 13 and 23) of the first element 11 may be between about 4 nm and 150 nm, for example of the order of 70 nm, and the thickness of the first insulating layer 13 may be between about 50 nm and 300 nm, for example of the order of 120 nm. The thickness of the second element 21 may be between about 4 nm and 150 nm, for example of the order of 6 nm, and the thickness of the second insulating layer 23 may be between about 100 nm and 300 nm, for example of the order of 150 nm.

A third level comprising at least one third element will be located on the second level. Successive steps in the formation of a contact that will electrically connect the first element 11 of the first level to a third element of the third level are described below with reference to FIGS. 1B-1G, the contact being electrically insulated from the second element 21 of the second intermediate level.

FIG. 1B illustrates the formation of an opening 25 passing through the second insulating layer 23 and at least opening up partly on the second element 21. For example, the opening 25 is formed by photolithography and then etching.

As shown, the opening 25 opens up partly on the second element 21. According to one alternative, the opening 25 may open up entirely on the second element 21.

In this example embodiment, during this step, the opening 25 is formed as far as the first insulating layer 13.

The etching method is chosen so as to selectively etch the material of the second insulating layer 23 relative to the material of the second element 21 and relative to the material of the first insulating layer 13.

Selective etching of a first material relative to a second material means that the etching rate of the first material is significantly higher, for example about three times higher, than the etching rate of the second material.

Once the opening 25 has been formed, a portion 27 of the second element 21 is exposed in the opening 25.

FIG. 1C illustrates isotropic etching of the second element 21, from the exposed portion 27 of the second element 21. Etching is done so as to eliminate a part of the second element 21 located between the first insulating layer 13 and the second insulating layer 23, in addition to the exposed portion 27 of the second element 21.

The result is thus a cavity 30 between the first insulating layer 13 and the second insulating layer 23.

The depth r₁ of the cavity 30 may for example be between a few Angstroms and a few tens of nanometers.

For example, such etching may be wet TMAH type etching.

FIG. 1D illustrates the deposition, in this case corresponding for example to an ALD (atomic layer deposition) type of conforming deposition of a dielectric material 34, for example SiN, on the second insulating layer 23, on the walls and on the bottom of the opening 25, and in the cavity 30. The thickness of the dielectric material layer 34 is for example between about 10 nm and 20 nm, for example equal to about 13 nm.

The depth r₁ of the cavity 30, the thickness e₂₁ of the second element 21 and the thickness e₁ of the dielectric material 34 are chosen for example such that the dielectric material 34 fills the cavity 30 entirely. The dielectric material 34 may possibly cover the walls and the bottom of the cavity 30 without completely filling the cavity 30.

FIG. 1E illustrates elimination of the dielectric material 34, except in the cavity 30. The dielectric material 34 may for example be eliminated by wet etching (for example by a first HF etching applied for a few seconds to remove the native oxide and then a second H₃PO₄ type wet etching to remove the remainder of the dielectric material 34 except in the cavity 30).

Therefore, a remaining portion of the layer of dielectric material 34 forms a spacer 22 located between the second element 21 and the opening 25. The width W₁ of the spacer 22 corresponds for example to the depth r₁ of the cavity 30 formed during the step shown in FIG. 1C. The width W₁ of the spacer 22 may for example be between a few Angstroms and a few tens of nanometers.

FIG. 1F illustrates the prolongation of the opening 25 through the first insulating layer 13, until reaching the first element 11, for example by etching. The etching method is chosen so as to selectively etch the material of the first insulating layer 13 relative to the dielectric material of the spacer 22 and relative to the dielectric material of the second insulating layer 23.

FIG. 1G illustrates filling of the opening 25 with at least one conducting material 37. A barrier layer that in this case is electrically conducting may be formed beforehand at least on the walls of the opening. This barrier layer will prevent diffusion of the conducting material 37 to the insulating layers 13, 23 and to the spacer 22 and/or improve bonding of the conducting material 37. Thus, the opening 25 may for example be filled by deposition of a Ti/TiN bilayer type barrier layer, and then deposition of a tungsten growth layer by ALD deposit, then a CVD deposition of tungsten from B₂H₆ and WF₆.

The result is thus the formation of a contact 37 to electrically connect the first element 11 to a third element of a third level that will be formed on the second level comprising the second element 21. The contact 37 is electrically insulated from the second element 21 of the second level by the spacer 22.

One advantage of a method like that described with reference to FIGS. 1A-1G lies in the reduction of the distance between the contact 37 and the second element 21, because the opening 25 is made initially at least partly facing the second element 21 and the contact 37 is insulated from the second element 21 by the spacer 22 judiciously located between the second element 21 and the contact 37, at the second element 21. The result is an increase in the integration density.

Another advantage of a method like that described with reference to FIGS. 1A-1G lies in the fact that it cannot be used to form a contact with a small diameter (or width) D₁, for example of the order of a few nanometers. This is due to the fact that the spacer 22 is not formed in the opening 25 of the contact but is located between the insulating layers 13 and 23, adjacent to the opening 25.

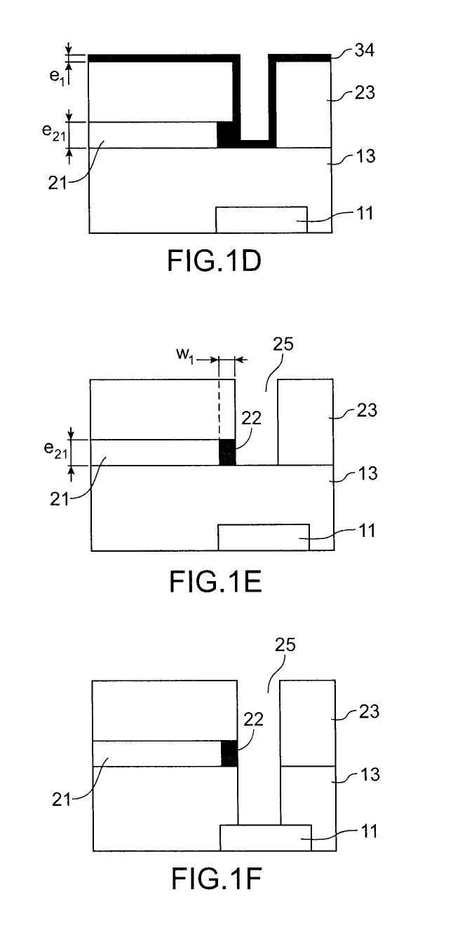

FIGS. 2A to 2D are sectional views diagrammatically illustrating successive steps in a variant of the method in FIGS. 1A-1G.

As described above with reference to FIG. 1B, the first step is to form an opening 25 on the second element 21.

FIG. 2A illustrates isotropic etching of the access zone 21 starting from the portion 27 of the second element 21 that was exposed during formation of the opening 25. In addition to the exposed portion 27 of the second element 21, part of the second element 21 arranged between the first insulating layer 13 and the second insulating layer 23 and adjacent to the portion 27 is etched so as to form the cavity 30 between the first insulating layer 13 and the second insulating layer 23.

According to this variant, the depth r₂ of the cavity 30 is large, for example between about 10 nm and 40 nm, for example of the order of 20 nm. The thickness e₂₁ of the second element 21 is small, for example between a few nanometers and a few tens of nanometers, for example of the order of 6 nm.

FIG. 2B illustrates deposition of the dielectric material 34 on the second insulating layer 23, on the walls and the bottom of the opening 25 and in the cavity 30. This deposition is such that the dielectric material 34 only partially fills the cavity 30.

After deposition of the dielectric material 34, a part 35 of the cavity 30 is not filled with dielectric material 34. The remaining part 35 of the cavity 30, arranged between the second element 21 and the dielectric material 34, may for example be filled with ambient air that was present in the deposition equipment during deposition of the dielectric material 34.

FIG. 2C illustrates elimination of the dielectric material 34, except in the cavity 30. For example, the dielectric material 34 may be eliminated by etching.

The result is thus the formation of an insulation zone 36 between the second element 21 and the contact currently being formed, in other words between the second element 21 and the opening 25. The insulation zone 36 comprises the remaining portion of the dielectric material 34, in other words the spacer 22, and the part 35 of the cavity 30 that is filled with air and therefore that also forms a dielectric element located between the opening 25 and the second element 21.

For example, the width W₂ of the spacer 22 may be between a few Angstroms and a few tens of nanometers.

FIG. 2D illustrates the prolongation of the opening 25 as far as the first element 11 and filling of the opening 25 by the conducting material 37 (and possibly by the prior deposition of an electrically conducting barrier layer). These steps correspond to the steps described with reference to FIGS. 1F-1G and will not be described again below.

The result is thus the formation of a contact 37 to electrically connect the first element 11 to a third element of a third level that will be formed on the second level comprising the second element 21. The contact 37 is electrically insulated from the second element 21 of the second level by the insulation zone 36.

One advantage of a method like that described with reference to FIGS. 2A-2D lies in the fact that it can be used to form a contact with a small diameter (or width) D₂, for example of the order of a few nanometers. This is related to the fact that the insulation zone 36 is not formed in the opening 25 of the contact but is located between the insulating layers 13 and 23, adjacent to the opening 25.

One advantage of the variant described with reference to FIGS. 2A-2D over a method like that shown in FIGS. 1A-1G lies in the fact that the electrical insulation between the contact and the second element 21 for a spacer 22 with the same width and the same nature, is better due to the cavity 35.

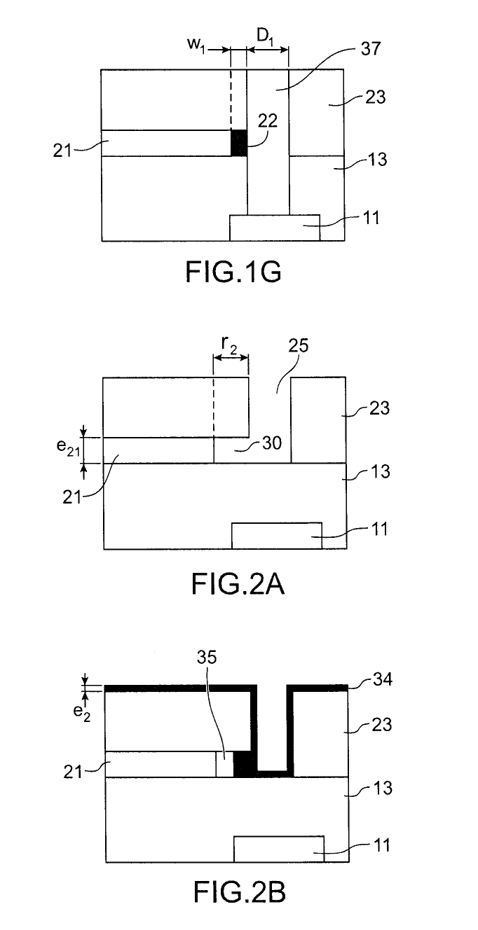

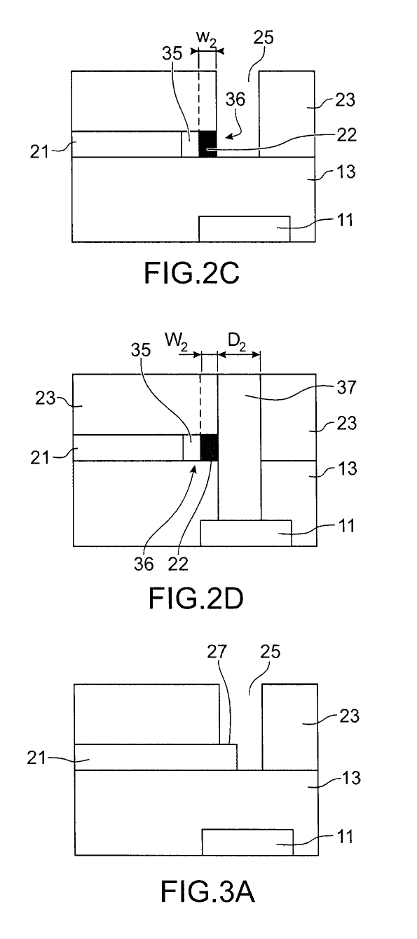

FIGS. 3A to 3D are sectional views diagrammatically illustrating successive steps of another method of making a self-aligned 3D contact.

FIG. 3A corresponds to the step illustrated in FIG. 1B of the method described with reference to FIGS. 1A-1G and will not be described again below. An opening 25 is formed on the second element 21.

According to this embodiment, the opening 25 is formed so as to open up only partly on the second element 21.

FIG. 3B illustrates local oxidation of the portion 27 of the second element 21 that was exposed during formation of the opening 25.

According to this embodiment, the second element 21 is made of a material that oxidises, for example silicon.

The exposed portion 27 of the second element 21 may be oxidised by so-called tilted implantation. Tilted implantation means that elements are implanted through one face of a substrate at a certain angle relative to a direction perpendicular to this face of the substrate. If the second element 21 is made of silicon, the exposed portion 27 of the second element 21 may for example be oxidised by implantation of oxygen. With such an implantation, part of the second element 21 that is not exposed in the opening 25 but that is adjacent to the portion 27 and that is located between the insulating layers 13 and 23 may also be oxidised. FIG. 3B shows that a first part of the spacer 52 formed by this oxidation by implantation is covered by the insulating layer 23, and that a second part of the spacer 52 corresponds to the portion 27 that is oxidised. However, as a variant, it is possible that the spacer 52 is formed by the oxidised portion 27 only. According to one variant, oxidation of the exposed portion 27 of the second element 21 may correspond to surface oxidation and may be done using a plasma, for example by a method currently designated in the state of the art by the term PLAD (<<PLAsma Doping>>). This surface oxidation may also be done in a capacitively or inductively coupled chamber. The result of such surface oxidation is illustrated in FIG. 3C, in which it can be seen that oxide is formed on the surface of the portion 27.

Thus, a spacer 52 is formed comprising a dielectric material between the second element 21 and the contact currently being formed. According to this example embodiment, the spacer 52 is not located between the insulating layers 13 and 23, but is located in the opening 25.

FIG. 3D illustrates the prolongation of the opening 25 through the first insulating layer 13, as far as the first element 11, for example by etching. The etching method is chosen so as to selectively etch the material of the first insulating layer 13 relative to the dielectric material of the spacer 52 and relative to the dielectric material of the second insulating layer 23.

Due to the presence of the spacer 52 in the opening 25, the diameter (or width) of the opening 25 is larger in the part in which it passes through the second insulating layer 23 than in the part in which it passes through the first insulating layer 13. The diameter (or width) of the opening in the part in which it passes through the first insulating layer 13 is denoted D₃. A sufficiently large opening 25 will be formed during the step illustrated in FIG. 3A such that the diameter D₃ of the contact is sufficient to satisfy the target application.

FIG. 3E illustrates filling of the opening 25 by at least one conducting material 57. A barrier layer may be formed in advance, in this case an electrically conducting layer located at least on the walls of the opening. This barrier layer will prevent diffusion of the conducting material 57 to the insulating layers 13, 23 and to the spacer 52 and/or facilitate bonding of the conducting material 57.

The result thus formed is a contact 57 that will electrically connect the first element 11 to a third element of a third level that will be formed on the second level comprising the second element 21. The contact 57 is electrically insulated from the second element 21 of the second level by the spacer 52.

One advantage of a method like that described with reference to FIGS. 3A-3E lies in the reduction of the distance between the contact 57 and the second element 21, due to the fact that the opening 25 is initially made at least partly facing the second element 21 and in that the contact 57 is insulated from the second element 21 by the spacer 52. The result is an increase in the integration density.

Another advantage of a method like that described with reference to FIGS. 3A-3E lies in its small number of manufacturing steps. The spacer 52 is formed during a single oxidation step located at least in the exposed part 27 of the second element 21.

FIGS. 3F to 3I are sectional views diagrammatically illustrating successive steps in a variant of the method of making a self-aligned 3D contact previously described with reference to FIGS. 3A-3E.

As shown in FIG. 3F, the opening 25 is in this case formed so as to entirely open up on the insulating layer 13, and such that the opening 25 opens up adjacent to the second element 21 flush with the second element 21. Part of the lateral wall of the opening 25 is formed by the second element 21, corresponding to the portion 27 of the second element 21 that is exposed.

The portion 27 of the second element 21 accessible from the opening 25 is then oxidised, for example by oxidation done in a capacitively or inductively coupled chamber, thus forming the spacer 52 (FIG. 3G).

The result is thus that a spacer 52 is formed, comprising a dielectric material between the second element 21 and the contact currently being formed. In this variant, the spacer 52 is located between the insulating layers 13 and 23.

FIG. 3H illustrates the prolongation of the opening 25 through the first insulating layer 13, as far as the first element 11, for example by etching. The etching method is chosen so as to selectively etch the material of the first insulating layer 13 relative to the dielectric material of the spacer 52 and relative to the dielectric material of the second insulating layer 23.

Due to the presence of the spacer 52 between the insulating layers 13 and 23, the diameter (or width) of the opening 25 is very similar in the two insulating layers 13 and 23.

FIG. 3I illustrates filling of the opening 25 by at least one conducting material 57. The first step is to form a barrier layer that in this case is electrically conducting, located at least partly on the walls of the opening. This barrier layer will avoid diffusion of the conducting material 57 to the insulating layers 13, 23 and to the spacer 52 and/or facilitate bonding of the conducting material 57.

A contact 57 is thus formed that will electrically connect the first element 11 to a third element of a third level that will be formed on the second level comprising the second element 21. The contact 57 is electrically insulated from the second element 21 of the second level by the spacer 52.

The advantages of this method are similar to the advantages described previously for the method described in FIGS. 3A-3E.

Different example embodiments and variants of a method of making a self-aligned 3D contact have been described above for the case in which the nature of the insulating layers 13 and 23 is different. The following describes a variant that can be used in the case in which the nature of the insulating layers 13 and 23 is the same.

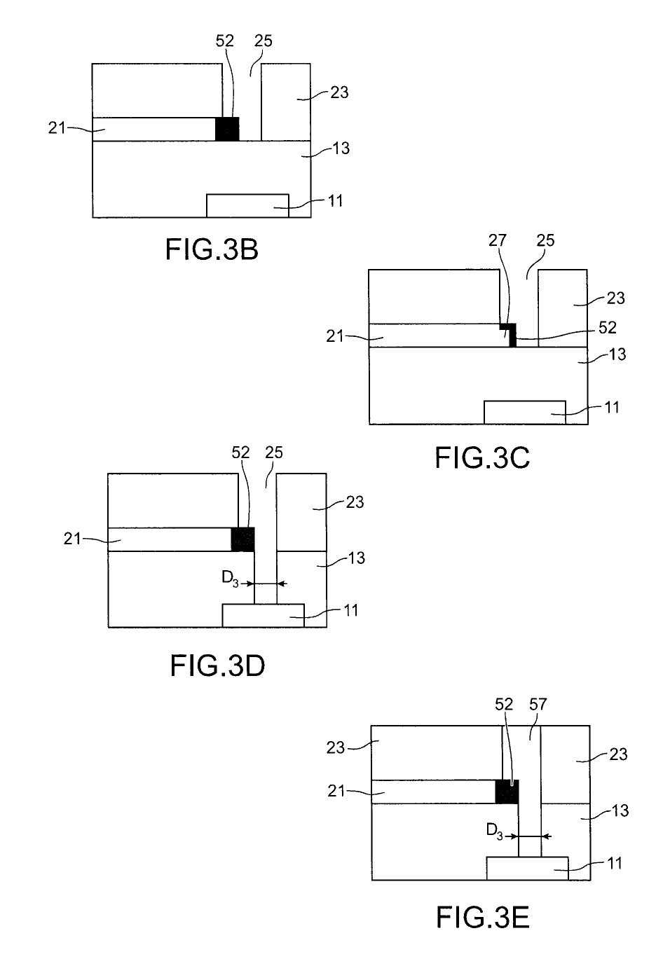

FIGS. 4A to 4D are sectional views that diagrammatically illustrate successive steps in a variant of a method described with reference to FIGS. 1A-1G, in the case in which the insulating layers 13 and 23 comprise the same dielectric material 73.

FIG. 4A illustrates the formation of a single opening 25 self-aligned on the second element 21. The opening 25 passes through the dielectric material 73 and opens up at least partly on the second element 21.

This opening 25 is made by forming a hard stencil, for example comprising TiN and between about 15 and 50 nm thick (for example 35 nm), on the insulating layer 23. The thickness of this hard stencil is chosen such that it is more than the thickness of dielectric material that will subsequently be deposited in the opening 25 to form the spacer 22. A hard TiN stencil has the advantage that it has good resistance to the SiO₂ etching plasma that corresponds to the dielectric material 73.

An antireflection layer is then deposited on the hard stencil.

The photolithography that will be used to form the opening 25 is then made in the antireflection layer, and the photolithography pattern is then transferred in the hard stencil. The antireflection layer and the hard stencil are then etched according to the photolithographed pattern, for example by plasma. Examples of radicals that can be used during the TiN plasma etching are F, CFx, H, CI and BCIx.

The dielectric material 73 is then partially etched.

According to this variant, the opening 25 is formed by partial etching of the dielectric material 73. The opening 25 passes through the second insulating layer 23 and part of the first insulating layer 13.

Once the opening 25 has been formed, a portion 27 of the second element 21 is exposed. This portion 27 may for example be etched in a capacitively coupled chamber with C₄F₈type fluorocarbon chemistry.

FIG. 4B illustrates isotropic etching of the second element 21, from the exposed portion 27 of the second element 21. In addition to the exposed portion 27 of the second element 21, part of the second element 21 located between the first insulating layer 13 and the second insulating layer 23 and adjacent to the portion 27 is etched so as to form a cavity 30 between the first insulating layer 13 and the second insulating layer 23. The depth of the cavity 30 may for example be between about 5 nm and 15 nm, and for example equal to about 8 nm. Isotropic etching corresponds for example to selective TMAH type wet etching relative to the dielectric material 73.

FIG. 4C illustrates the formation of a spacer 22 comprising a dielectric material in the cavity 30, between the second element 21 and the contact currently being formed. This is done by depositing a dielectric material and then etching this dielectric material as described above with reference to FIGS. 1D and 1E.

FIG. 4D illustrates prolongation of the opening 25 and its filling with at least one conducting material 37. The opening 25 is prolonged through the dielectric material 73, as far as the first element 11, for example by etching with fluorocarbon chemistry. The etching method is chosen so as to selectively etching the dielectric material 73 relative to the dielectric material of the spacer 22. Contact bottoms can be cleaned before the conducting material 37 is formed. The hard stencil is also removed.

A barrier layer may be formed at least on the walls of the opening before the conducting material 37 is formed.

The result is thus that a contact 37 is formed that will electrically connect the first element 11 to a third element of a third level that will be formed on the second level comprising the second element 21. The contact 37 is electrically insulated from the second element 21 of the second level by the spacer 22.

A variant like that illustrated with reference to FIGS. 4A-4D can be used in the case of the variant in FIGS. 2A-2D and in the case of example embodiments in FIGS. 3A-3D. With the variant in FIGS. 4A-4D, the opening self-aligned on the second element 21 is formed by partial etching of the dielectric material 73 and not by etching stopping on the first insulating layer 13.

The above description has disclosed different example embodiments and different variants of a method of forming a self-aligned 3D contact. As was described, during formation of the self-aligned opening that will form the contact, the opening is formed so as to at least partially open up on the second element 21 of the second level. Except in the case of the example embodiment in FIGS. 3A-3D, the opening may open up entirely on the second element 21.

In the above, we have described different example embodiments and different variants of a method of making a self-aligned 3D contact so as to electrically connect elements of two non-adjacent levels separated by a single intermediate level. Obviously, the methods described above can be used to electrically connect elements of two non-adjacent levels separated by several intermediate levels.

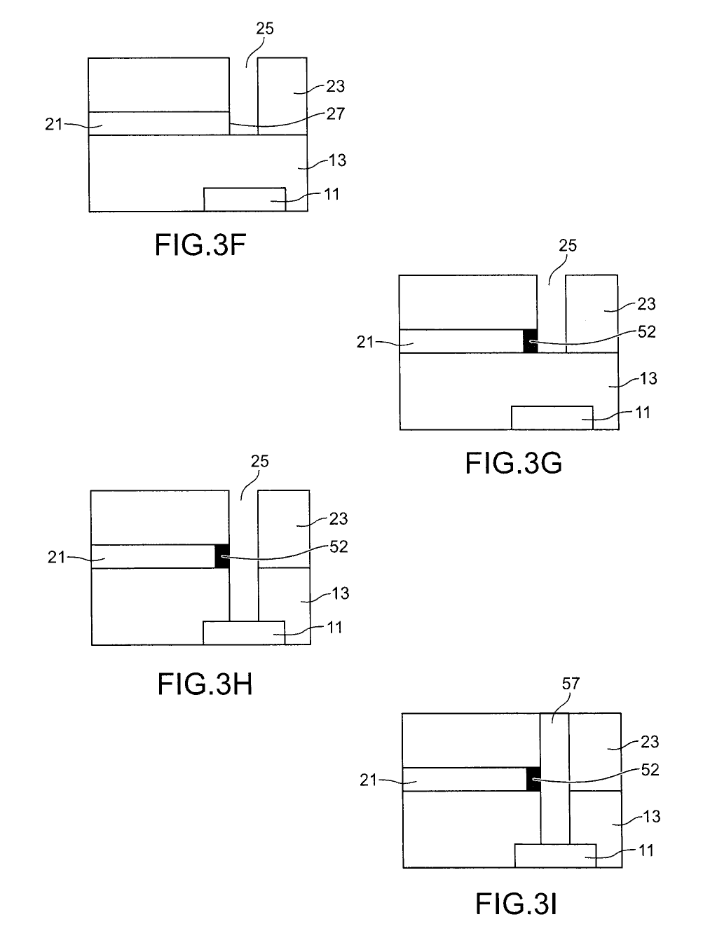

FIG. 5 illustrates a sectional view diagrammatically illustrating an example structure obtained by a method of the type described with reference to FIGS. 1A-1G.

The structure comprises a lower level comprising a lower element 11 covered by an insulating layer 13. The insulating layer 13 is covered by three intermediate levels each comprising an access zone 21, 31, 41 covered by an insulating layer 23, 33, 43.

A contact 37 is formed that will electrically connect the lower element 11 to an element of a higher level that will be formed on the insulating layer 23. The contact 37 is electrically insulated from each access zone 21, 31, 41 of intermediate levels by a spacer 22, 32, 42.

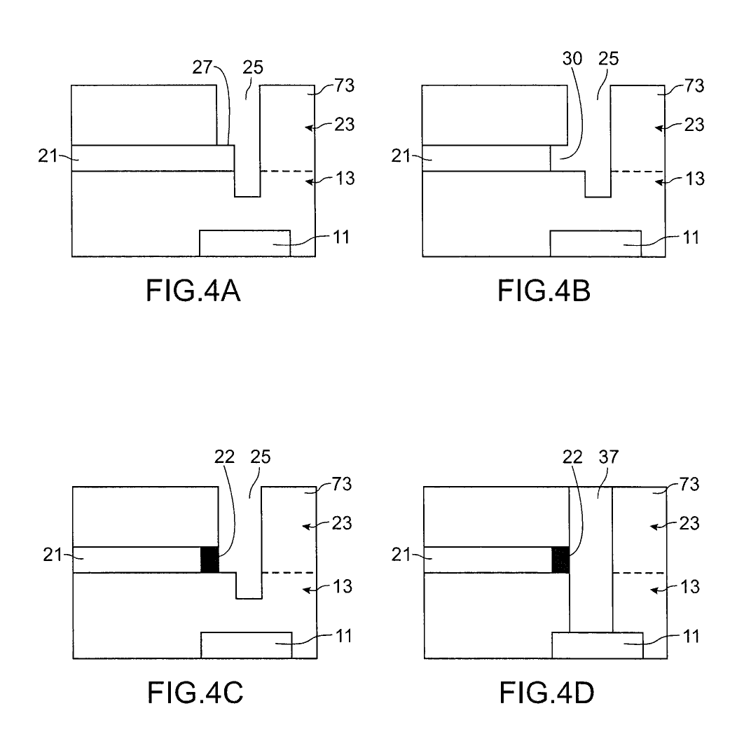

FIG. 6 is a sectional view diagrammatically representing an example structure obtained by a method of the type described with reference to FIGS. 1A-1G, for example as part of monolithic 3D integration.

The first element 11 of the first level comprises a metallic line. The second element 21 of the second level comprises an active zone of a transistor T. A contact 37 electrically connects the metallic line 11 of the first level to a metallic line 51 of a third level formed on the second level. The contact 37 is electrically insulated from the active zone 21 of the second level by a spacer 22, particularly so as to not deteriorate the performances of the transistor T.

Although FIG. 6 corresponds to the case in which the contact 37 passes through a single level comprising an active transistor zone, the contact 37 could obviously pass through several levels comprising active transistor zones.

A method of the same type as those described above can be used to electrically connect metallic lines of non-adjacent levels, the contact being electrically insulated from active zones of devices of the intermediate levels passed through.

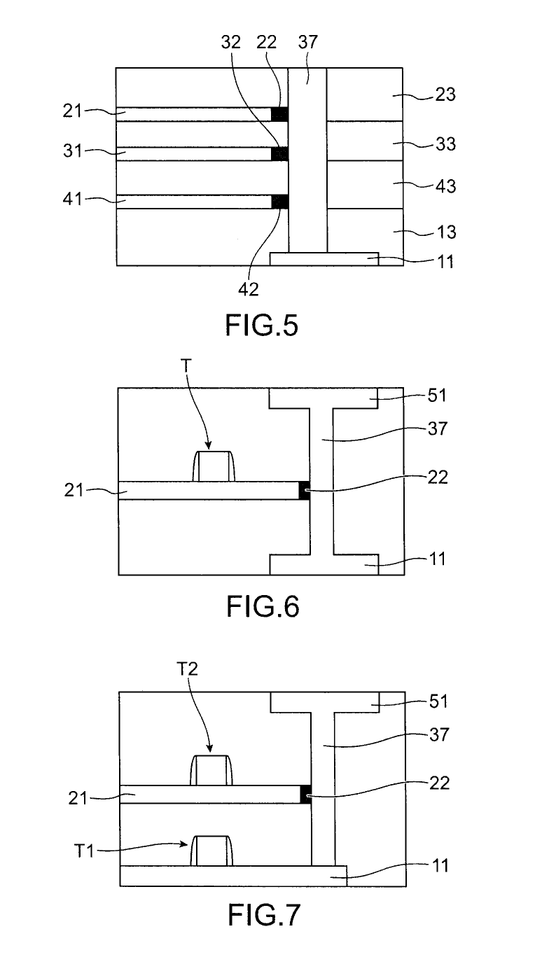

FIG. 7 is a sectional view diagrammatically representing another example structure obtained by a method of the type described with reference to FIGS. 1A-1G, for example as part of the monolithic 3D integration.

The first element 11 of the first level comprises an active zone of a transistor T1. The second element 21 of the second level comprises an active zone of a transistor T2. A contact 37 electrically connects the active zone 11 of the first level to a metallic line 51 of a third level formed on the second level. The contact 37 is electrically insulated from the active zone 21 of the second level by a spacer 22, that in particular avoids deteriorating performances of the transistor T2.

Although FIG. 7 corresponds to the case in which the contact 37 passes through a single level comprising an active transistor zone, obviously the contact 37 can pass through several levels comprising active transistor zones.

A method of the type described above can be used to electrically connect a metallic line of a high level and an active zone of devices of a non-adjacent lower level, the contact being electrically insulated from the active zones of devices of intermediate levels passed through.

The first element 11 in the different examples and variant embodiments described above may be an active zone of a device or a conducting line of an intermediate level. The second element 21 may be an access zone to a device, for example an active zone of a device or a conducting line of an intermediate level.

Example materials include:
the first element 11 comprises at least one semiconducting material, for example a silicide semiconducting material or at least one conducting material, for example a metallic material;
the second element 21 comprises at least one semiconducting material, for example a silicide semiconducting material, or at least one conducting material, for example a metallic material. The semiconducting material may be crystalline or polycrystalline;
the contact 37 comprises at least one conducting material, for example a metallic material or a doped semiconducting material, for example polycrystalline silicon or SiGe; and
the spacer 22, 52 comprises at least one dielectric material, chosen particularly as a function of the dielectric coupling to be provided between the contact and the second element.

1. A method of making an integrated circuit, comprising at least the following steps:
a) form a first semiconducting or conducting element, covered with a first insulating layer on which a second semiconducting or conducting element is arranged, covered with a second insulating layer;
b) form an opening passing through at least the second insulating layer, exposing a portion of the second element and opening up at least partly on the second element or adjacent to the second element;
c) form a spacer located at the second element and comprising at least one dielectric material located at least between the second element and the opening;
d) prolong the opening through the first insulating layer as far as the first element;
e) fill the opening with at least one conducting material, so as to form a contact;
and in which step c) to form the spacer comprises at least the following steps:
isotropic etching of a part of the second element including at least said portion of the second element, so as to form a cavity located between the first and second insulating layers;
deposit at least one dielectric material at least on the walls of the opening and in the cavity; and
eliminate the dielectric material except in the cavity.

2. The method according to claim 1, in which during step b), the opening is formed as far as the first insulating layer.

3. The method according to claim 1, in which the first and second insulating layers have the same nature and in which during step b), the opening passes partly through the first insulating layer.

4. The method according to claim 1, in which a dimension (r₂) of the cavity approximately perpendicular to the principal axis of the opening is such that part of the cavity is not filled with dielectric material after deposition of the dielectric material.

5. The method according to claim 1, in which during step b), the opening is formed so as to open up only partly on the second element.

6. The method according to claim 1, in which during step e) to fill the opening, an electrically conducting barrier layer is previously formed in the opening before formation of the conducting material.

7. The method according to claim 1, in which the first element is an active zone of at least a first transistor or a first metallic line, and/or in which the second element is an active zone of at least one second transistor or a second metallic line.

8. The method according to claim 1, in which during step a), at least one semiconducting or conducting intermediate element, covered with an intermediate insulating layer is arranged between the first insulating layer and the second element, and also comprising the following steps performed for the or each intermediate element, between steps c) and d):
prolong the opening through the intermediate insulating layer covering said intermediate element, such that the opening exposes a portion of said intermediate element and opens up at least partly on said intermediate element or adjacent to said intermediate element; and
form an intermediate spacer located at said intermediate element and comprising at least one dielectric material arranged at least between said intermediate element and the opening.
